(19) United States
(12) Patent Application Publication
(10) Pub. No.: US 2009/0305447 A1
(43) Pub. Date: Dec. 10, 2009

(54) IMPLANTED VERTICAL CAVITY SURFACE EMITTING LASER

(75) Inventor: James K. GUENTER, Garland, TX (US)

Correspondence Address: MUNSCH, HARDT, KOPF & HARR, P.C.;INTELLECTUAL PROPERTY DOCKET CLERK, 3800 LINCOLN PLAZA, 500N AKARD STREET, DALLAS, TX, 75201, US

(73) Assignee: FINISAR CORPORATION, Sunnyvale, CA (US)

(21) Appl. No.: 12/134,372

(22) Filed: Jun. 6, 2008

(51) Int. Cl. H01L 21/02

(52) U.S. Cl. 438/39; 438/45; 257/E21.002

(57) ABSTRACT

A method of forming a gain guide implant for a vertical cavity surface emitting laser (VCSEL) comprises implanting ions into a wafer to simultaneously form a first non-conducting portion of the gain guide implant spaced apart from an active region and a second non-conducting portion of the gain guide implant occupying the active region, the first non-conducting portion laterally offset relative to the second non-conducting portion.

### BACKGROUND

A vertical cavity surface emitting laser (VCSEL) represents a relatively new class of semiconductor laser. While there are many variations of VCSELs, in a typical VCSEL, optical emission occurs normal to the plane of a p-n junction and/or a top surface of the device. The VCSEL generally includes a gain guide, which provides an insulating or non-conducting region, disposed within a top mirror stack (e.g., a distributed Bragg reflector (DBR)). The gain guide is formed by implanting ions into the top mirror stack or by developing an oxide layer in the top mirror stack. In either case, the gain guide causes current confinement within the VCSEL such that lasing will occur within an active region of the VCSEL.

In addition to the gain guide, the VCSEL may also include an isolation implant that provides an additional insulating or non-conducting region. The isolation implant generally extends through the active region of the VCSEL, in a direction transverse to mirror layers of the top mirror stack, to provide device-to-device electrical isolation and to isolate and laterally constrain incipient dislocations that may be created near or within an exposed surface of the active region when the VCSEL is separated from a wafer (e.g., by sawing, etching, cleaving, laser cutting, etc.).

### BRIEF DESCRIPTION OF THE DRAWINGS

The accompanying drawings incorporated in and forming a part of the specification illustrate several aspects of the present disclosure and, together with the description, serve to explain the principles of the present disclosure. In the drawings:

FIG. 1 is an elevation view of one embodiment of a VCSEL formed according to the teachings of the present disclosure;

FIGS. 2A-2E are diagrams illustrating a method of forming the VCSEL of FIG. 1;

FIG. 3 is an elevation view of another embodiment of a VCSEL formed according to the teachings of the present disclosure;

FIGS. 4A-4F are diagrams illustrating a method of forming the VCSEL of FIG. 3;

FIG. 5 is an elevation view of another embodiment of a VCSEL formed according to the teachings of the present disclosure;

FIGS. 6A-6F are diagrams illustrating a method of forming the VCSEL of FIG. 5;

FIG. 7 is an elevation view of another embodiment of a VCSEL formed according to the teachings of the present disclosure;

FIGS. 8A-8E are diagrams illustrating a method of forming the VCSEL of FIG. 7;

FIG. 9 is an elevation view of another embodiment of a VCSEL formed according to the teachings of the present disclosure;

FIGS. 10A-10F are diagrams illustrating a method of forming the VCSEL of FIG. 9;

FIG. 11 is a top plan view of one embodiment of the VCSEL of FIG. 1; and

FIG. 12 is a top plan view of another embodiment of the VCSEL of FIG. 1.

### DETAILED DESCRIPTION OF THE DRAWINGS

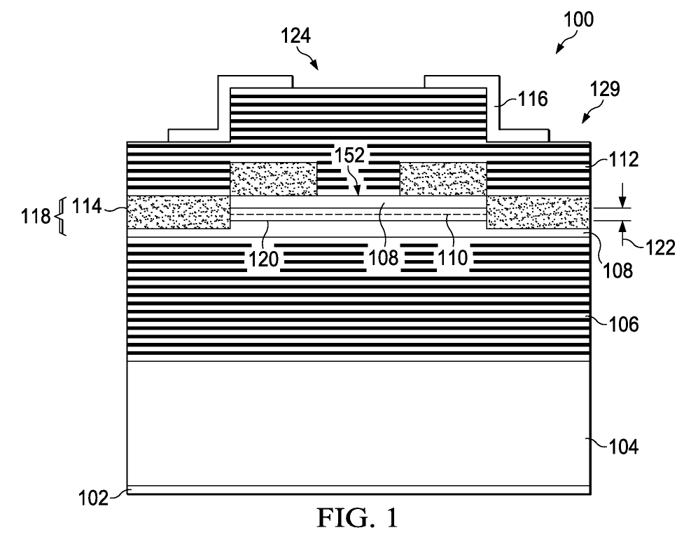

Referring now to FIG. 1, a VCSEL 100 is illustrated. As will be more fully explained below, VCSEL 100 is constructed in such a manner that both a gain guide implant and an isolation implant are produced through a single implant operation. In the embodiment illustrated in FIG. 1, VCSEL 100 includes a lower electrical contact 102, a substrate 104, a lower mirror stack 106, a non-mirror layer 108 including a p-n junction 110 having a number of quantum wells, a top mirror stack 112, a gain guide implant 114, and a top electrical contact 116. While VCSEL 100 may also include, use, or support a myriad of other intricate structures, features, and mechanisms (e.g., such as those in VCSEL 10 or other known VCSELs), for the purpose of convenient illustration those components have not been specifically depicted in FIG. 1. Even so, one or more of the components may nonetheless be incorporated into, found on, or used in conjunction with VCSEL 100 illustrated in FIG. 1.

Still referring to FIG. 1, lower electrical contact 102 is generally metal (e.g., gold) and substrate 104 is a semiconductor (e.g., an n-type semiconductor). Despite being depicted as one piece in FIG. 1, lower electrical contact 102 may be formed in several discrete segments. Lower electrical contact 102 provides for electrical connection to and current flow through substrate 104 and is able to conduct heat away from substrate 104 during operation of VCSEL 100. In the embodiment illustrated in FIG. 1, substrate 104 is disposed on, or adjacent to, lower electrical contact 102. Substrate 104 may be formed from a variety of suitable materials such as, for example, GaAs, InP, and Si.

Lower mirror stack 106 is generally disposed upon substrate 104. In the illustrated embodiment of FIG. 1, lower mirror stack 106 is a distributed Bragg reflector (DBR) formed from an n-type material. Lower mirror stack 106 is constructed from alternating mirror layers, each layer about one-quarter of a wavelength thick and have differing refractive indices. In some embodiments, lower mirror stack 106 includes about thirty mirror layers, although more or fewer mirror layers may be used. Lower mirror stack 106 may be formed from a variety of suitable materials such as, for example, AlGaAs or other semiconductor layers. In some embodiments, lower mirror stack 106 is constructed from alternating layers of Al_{0.15}Ga_{0.85}As and Al_{0.95}Ga_{0.05}As. Lower mirror stack generally has a reflectance approaching 100% and, in most cases, much greater than 99%. Lower mirror stack 106, which is the non-exit mirror of VCSEL 100 illustrated in FIG. 1, generally has a greater reflectance than top mirror stack 112, through which light is emitted.

Non-mirror layer 108 is generally disposed upon lower mirror stack 106 and occupies an optical cavity 118, which is formed between lower mirror stack 106 and top mirror stack 112. Non-mirror layer 108, which is typically a non-mirror semiconductor, may be formed from a variety of suitable materials such as, for example, AlGaAs, InGaAlAs, InGaAsP, InGaAs, and InGaSb. In some embodiments, non-mirror layer 108 is formed from alternating layers of AlGaAs with different concentrations of Al. For example, one layer of AlGaAs in non-mirror layer 108 may have between twenty and thirty percent aluminum while an adjacent layer has between zero and five percent aluminum.

Still referring to FIG. 1, non-mirror layer 108 includes an active region 120 (a.k.a., a depletion region) where electron-hole pairs recombine, thereby emitting photons. As illustrated in FIG. 1, active region 120 encompasses, and generally extends above and below, p-n junction 110. Therefore, active region 120 is somewhat larger than p-n junction 110. A thickness 122 of active region 120, when measured in a direction generally transverse to the p-n junction 110, varies depending upon on the voltage applied across VCSEL 100 and, in particular, non-mirror layer 108. For example, if the voltage in the direction known as forward bias (i.e., positive voltage applied to a p-terminal) across non-mirror layer 108 decreases, thickness 122 of active region 120 increases. In contrast, if the forward-bias voltage across non-mirror layer 108 increases, then thickness 122 of active region 120 decreases. The area around p-n junction 110, which is disposed within active region 120, generally includes one or more quantum wells providing the gain to VCSEL 100. Each of the quantum wells within p-n junction 110 has a thickness of, for example, about 70 to 100 Angstroms.

Top mirror stack 112 is generally disposed upon non-mirror layer 108. In some embodiments, top mirror stack 112 is a distributed Bragg reflector (DBR) formed from a p-type material. Top mirror stack 112 is constructed from alternating mirror layers, each layer about one-quarter of a wavelength thick and have differing refractive indices. In some embodiments, top mirror stack 112 includes about twenty mirror layers, although more or fewer mirror layers may be used. Like lower mirror stack 106, top mirror stack 112 may be formed from a variety of suitable materials such as, for example, AlGaAs, a-Si, or other semiconductors, or MgF, MgO, WO, silicon oxides, silicon nitride, titanium dioxide, or other dielectrics. Semiconductor and dielectric layers may also be used in combinations, which results in some conducting and some non-conducting portions of the mirror. In some embodiments, top mirror stack 112 is constructed from alternating layers of Al_{0.15}Ga_{0.85}As and Al_{0.95}Ga_{0.05}As.

Still referring to FIG. 1, gain guide implant 114 is formed through an ion implantation process, which will be more fully explained below. It should be generally noted that during the ion implantation process, a wafer that is used to form VCSEL 100 is bombarded with ions of a suitable type including, for example, H⁺, He⁺, O⁺, Fe⁻, Ni⁺, and Be⁺. The ion bombardment of the wafer may be complemented with a rapid thermal annealing process. The ions penetrate the wafer and damage the crystal structures therein. Where crystal structures are damaged, the wafer becomes non-conducting, thereby forming the gain guide implant 114 shown in FIG. 1. In the embodiment illustrated in FIG. 1, gain guide implant 114 is shown as a discrete layer; however, it should be understood that the crystal damage caused during the ion implantation process may extend beyond the illustrated gain guide implant 114 (e.g., up through at least a portion of top mirror stack 112) on a diminishing basis. Because the highest concentration of crystal damage generally takes place within a area or region, gain guide implant 114 has been depicted as a discrete layer for the purposes of convenient illustration and description.

Top electrical contact 116 is generally a metal (e.g., gold) deposited on a p-type semiconductor material. Unlike the lower electrical contact 102, top electrical contact 116 generally includes a central aperture 124 where light is emitted during operation of VCSEL 100. Top electrical contact 116 may also act as a thermal device that conducts heat away from non-mirror layer 108 and, in particular, active region 120. Despite the configuration shown in FIG. 1, top electrical contact 116 may be formed in a single piece, limited to certain locations on VCSEL 100, and the like. Collectively, top electrical contact 116 and lower electrical contact 102 permit biasing of, and current flow though, VCSEL 100.

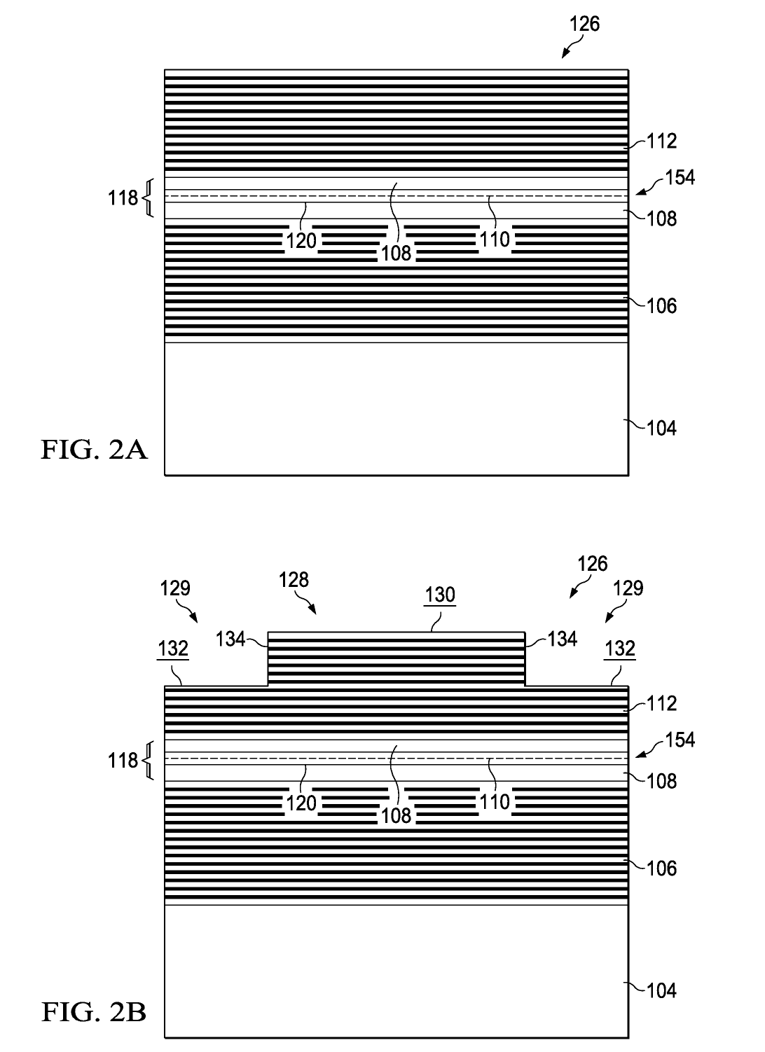

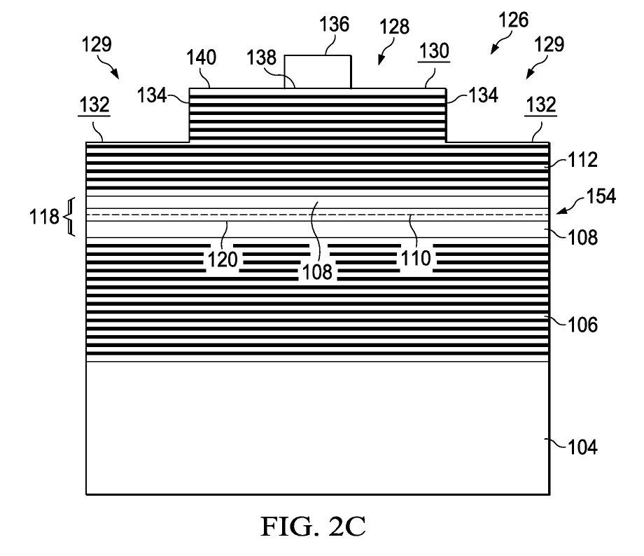

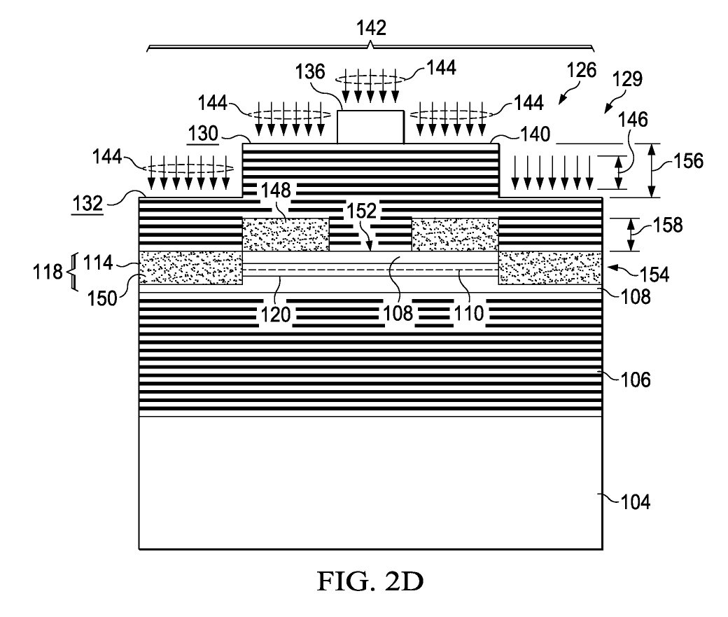

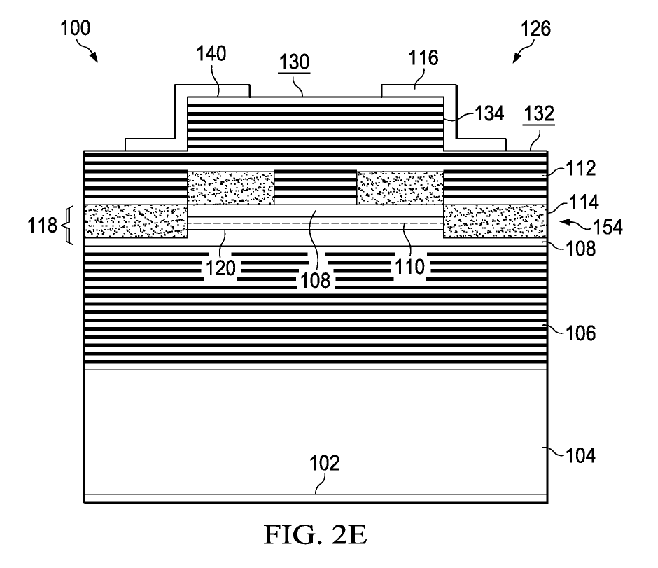

FIGS. 2A-2E are diagrams illustrating a method or process for forming VCSEL 100 of FIG. 1. As shown in FIG. 2A, the process begins with a wafer portion 126, which may be cut into an individual die used to form VCSEL 100. Wafer portion 126 may be cut or otherwise separated from a desired thickness of semiconductor material (e.g., a two to four inch wafer). As shown in FIG. 2A, wafer portion 126 generally includes substrate 104, lower mirror stack 106, non-mirror layer 108 with p-n junction 110, and top mirror stack 112.

Moving to FIG. 2B, in some embodiments, top mirror stack 112 is subjected to a photolithography process. During the photolithography process, top mirror stack 112 is patterned using a photomask and a light-sensitive chemical. Thereafter, top mirror stack 112 undergoes a series of chemical treatments to etch a desired pattern into top mirror stack 112 and form an elevated structure 128 as a result of removing portions of top mirror stack 112 from adjacent region 129. In the illustrated embodiment of FIG. 2B, because elevated structure 128 is formed by etching portions of top mirror stack 112, elevated structure 128 comprises mirror layers. However, elevated structure 128 may also be formed from other processes such as, for example, a lift-off process and may comprise a variety of different materials. In the embodiment illustrated in FIG. 2B, elevated structure 128 includes a top surface 130 offset from a neighboring mirror stack surface 132 by opposing side walls 134. Because side walls 134 are generally transverse with top surface 130 in the illustrated embodiment of FIG. 2B, elevated structure 128 resembles a mesa rising above a lower, etched portion of top mirror stack 112 in regions 129. Elevated structure 128 may nonetheless have a variety of other formations. In addition, elevated structure 128 need not be centered on wafer portion 126.

Referring to FIG. 2C, after elevated structure 128 has been formed, an implant resist 136, which inhibits or prevents the passage of ions therethrough, is placed on at least a portion of elevated structure 128. In FIG. 2C, implant resist 136 is seated on top surface 130 of elevated structure 128 in a central location. In some embodiments, implant resist 136 may be disposed above top surface 130 of elevated structure 128 and/or laterally offset from the center of elevated structure 128. The effectiveness of implant resist 136 depends upon a number of factors including, for example, the type and thickness of material used to construct implant resist 136, the acceleration implant energy used during an ion implantation process, and the like.

As illustrated in FIG. 2C, implant resist 136 generally divides top surface 130 into a covered portion 138 and an exposed portion 140. Covered portion 138, which is generally directly beneath implant resist 136, is shielded from ions accelerated toward top surface 130 during an ion implantation process. Therefore, the ions are unable to cause damage (or causes minimal damage) to the crystal structure of VCSEL 100 beneath covered portion 138. In contrast, exposed portion 140 and region 129, which are located outside the effective covered area of implant resist 136, are unprotected from ions accelerated toward top surface 130 and mirror stack surface 132 during an ion implantation process. Therefore, during an ion implantation process, the ions are able to enter the exposed portions of VCSEL 100 and cause damage to the crystal structure beneath exposed portion 140 and region 129.

With implant resist 136 situated on or above top surface 130 as shown in FIG. 2C, wafer portion 126 is subjected to an ion implantation process 142 as illustrated in FIG. 2D. During ion implantation process 142, wafer portion 126 is bombarded with ions in a direction represented by arrows 144. While the ions accelerated toward wafer portion 126 in FIG. 2D are depicted as being uniformly distributed across both top surface 130 of elevated structure 128 and neighboring mirror stack surface 132, in some embodiments, the ions may be otherwise distributed. In addition, while the ions are shown traveling along a path generally normal to top surface 130 and neighboring mirror stack surface 132, the ions may approach wafer portion 126 from other angles in other embodiments.

Still referring to FIG. 2D, except where implant resist 136 shields or masks covered portion 138, the ions accelerated toward wafer portion 126 during ion implantation process 142 are implanted into VCSEL 100. During ion implantation process 142, the ions are simultaneously implanted into exposed portions of wafer 126 unprotected by implant resist 136 (e.g., into and/or through elevated structure 128 in the location of exposed surface 140 and into a lower portion of top mirror stack 112 beneath neighboring mirror stack surface 132. The ions are also implanted during implantation process 142 using a predetermined level of acceleration implant energy, which is expressed in electron volts (eV) and represented in FIG. 2D by a length 146 of arrows 144, to cause damage and/or otherwise render non-conductive a portion of VCSEL 100 at a predetermined depth and/or a desired location. As used herein, the predetermined level of implant energy may be, for example, based on a single energy, based on a desired range of energies, and/or based on an average of different energies. In addition, the predetermined level of implant energy may be in the range of, for example, about 100 eV to about 1.5 MeV.

Still referring to FIG. 2D, the implantation of ions into a portion of VCSEL 100 unprotected by implant resist 136 (e.g., below exposed portion 140 and region 129) causes crystal damage that collectively produces gain guide implant 114. As shown in FIG. 2D, gain guide implant 114 includes an inner portion 148, which is disposed beneath exposed surface 140, and an outer portion 150, which is disposed beneath neighboring mirror stack surface 132 and laterally displaced relative to inner portion 148. As illustrated in FIG. 2D, inner portion 148 is also vertically offset from outer portion 150 as a result of ion implantation through a stepped or multi-level upper/top surface of wafer portion 126 (e.g., resulting from the formation of elevated structure 128). In some embodiments, inner portion 148 and outer portion 150 intersect and overlap such that gain guide implant 114 is generally a unitary structure and/or are otherwise a contiguous, non-conducting formation.

In the embodiment illustrated in FIG. 2D, inner portion 148 is disposed within top mirror stack 112 and offset above both active region 120 and p-njunction 110. In some embodiments, inner portion 148 may extend down into non-mirror layer 108. Inner portion 148 defines a conducting opening 152 passing through gain guide implant 114 corresponding to a location of implant resist 136 on top surface 130 of elevated surface 128. Because the crystal structure residing within the conducting opening 152 is not damaged (or minimally damaged) during ion implantation process 142, conducting opening 152 serves as a constricting conduit for current that flows during operation of VCSEL 100.

In the illustrated embodiment of FIG. 2D, outer portion 150 of gain guide implant 114 encompasses p-n junction 110 and spans entirely across active region 120 in a direction generally transverse to p-n junction 110. Because outer portion 150 is non-conducting, outer portion 150 effectively isolates any incipient dislocations that may result along a lateral edge of wafer 126, including where an exposed surface 154 (see also FIG. 2A) of p-n junction 110 is produced when wafer portion 126 is separated from the rest of the wafer. In other words, outer portion 150 assists in the lateral constraint of current within VCSEL 100 and prevents any defects, which may be generated during the separation process, from spreading inwardly into the portion of active region 120 where lasing occurs. Even though outer portion 150 of gain guide implant 114 extends almost entirely across non-mirror layer 108 in optical cavity 118 of FIG. 2D, outer portion 150 may be formed in a variety of other locations in other embodiments. For example, outer portion 150 may extend down into substrate 104 and lower mirror stack 106, may extend into top mirror stack 112, may remain exclusively within non-mirror layer 108, and the like. Thus, in some embodiments, the energy level used for ion implantation process 142 is selected such that outer portion 150 is located primarily in active region 120 (e.g., extending only slightly into top mirror stack 112 and/or lower mirror stack 106). Therefore, in operation, inner portion 148 of gain guide implant 114 functions as a gain guide or current constrictor while outer portion 150 functions as both a current constrictor and an isolation portion of gain guide implant 114 extending through active region 120.

In the embodiment illustrated in FIG. 2D, at least a portion of inner portion 148 of gain guide implant 114 intersects and/or overlaps with outer portion 150 by making a depth 156 of region 129 into top mirror stack 112 (measured from top surface 130 of elevated structure 128 to neighboring mirror stack surface 132) less than or equal to a thickness 158 of inner portion 148 of gain guide implant 114. By forming depth 156 as noted above, inner portion 148 and outer portion 150 of gain guide implant 114 vertically self-align with each other to at least partially intersect and/or overlap as shown in FIG. 2D. Therefore, inner portion 148 and outer portion 150 of gain guide implant 114 are formed without an intervening conducting gap therebetween where current could undesirably leak. In other words, inner portion 148 and outer portion 150 of gain guide implant 114 are formed as an uninterrupted and/or contiguous non-conducting formation.

After gain guide implant 114 has been formed by ion implantation process 142 of FIG. 2D, implant resist 136 is removed and top electrical contact 116 is added to wafer portion 126 as shown in FIG. 2E. While top electrical contact 116 is shown in two separate and distinct parts, a single electrical contact may also be employed. In the embodiment illustrated in FIG. 2E, top electrical contact 116 is applied over a portion of exposed portion 140 of top surface 130, along side wall 134 of elevated structure 128, and over a portion of neighboring mirror stack surface 132 adjacent elevated structure 128. However, in some embodiments, top electrical contact 116 may be otherwise oriented and configured. In addition, because a portion of top electrical contact 116 progresses down side wall 134 and/or along neighboring mirror stack surface 132, top electrical contact 116 is moved closer to active region 120 of VCSEL 100, thereby facilitating a transfer of heat away from active region 120.

Either before, after, or at the same time as top electrical contact 116, lower electrical contact 102 is provided on wafer portion 126. As shown in FIG. 2E, lower electrical contact 116 is generally disposed beneath substrate 102 to form VCSEL 100 as shown in FIG. 1. Lower electrical contact 102 and top electrical contact 116 collectively permit biasing of VCSEL 100 such that a current flows in a constricted path therethrough, photons are generated, and light is emitted from VCSEL 100 through central aperture 124 (FIG. 1).

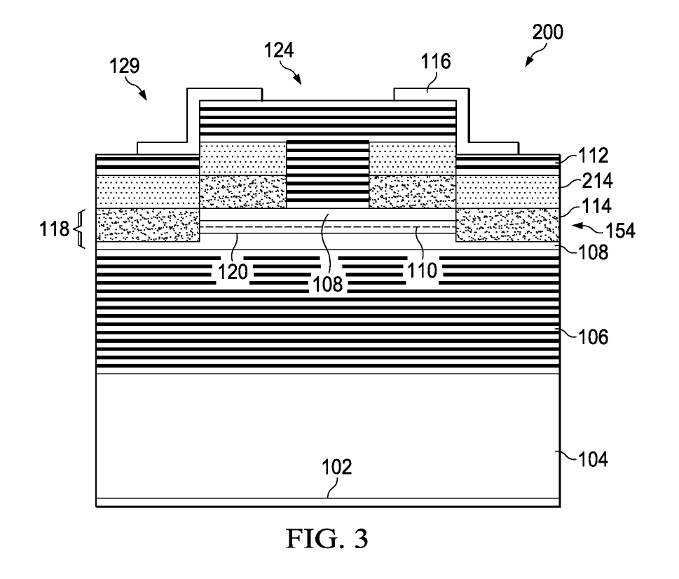

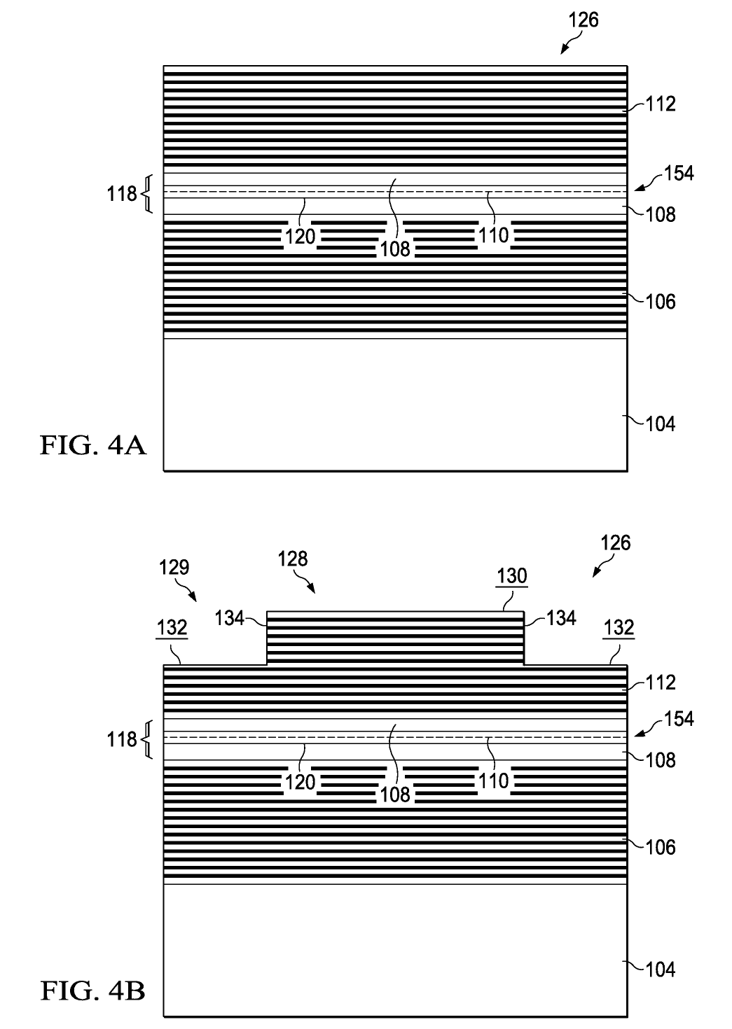

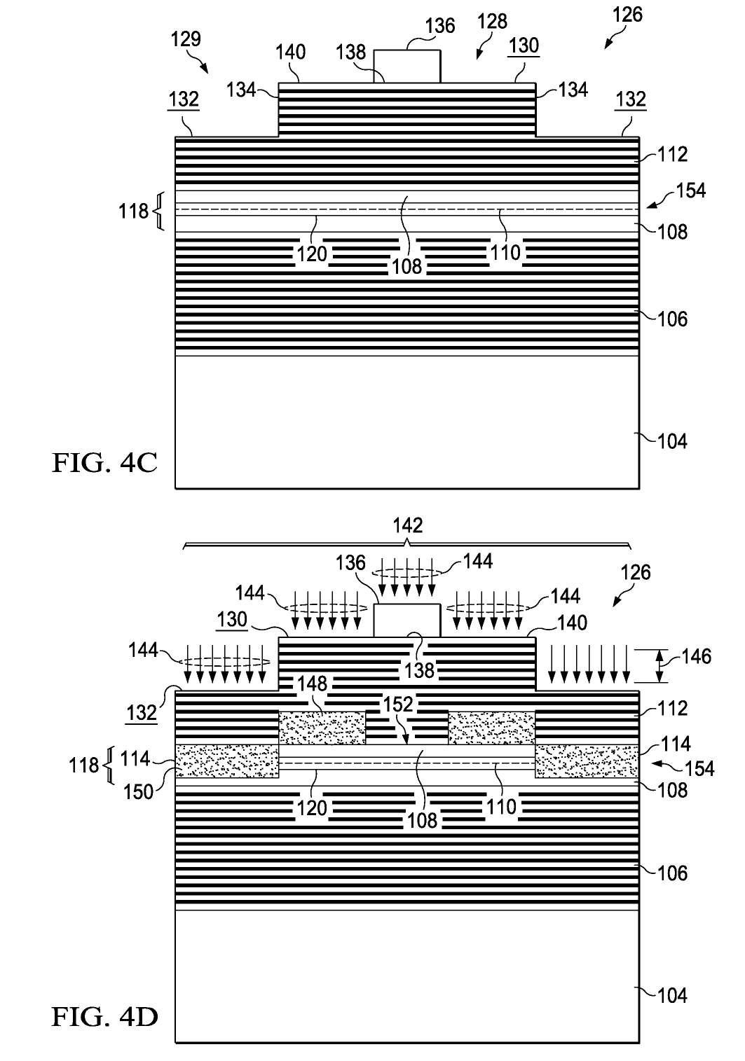

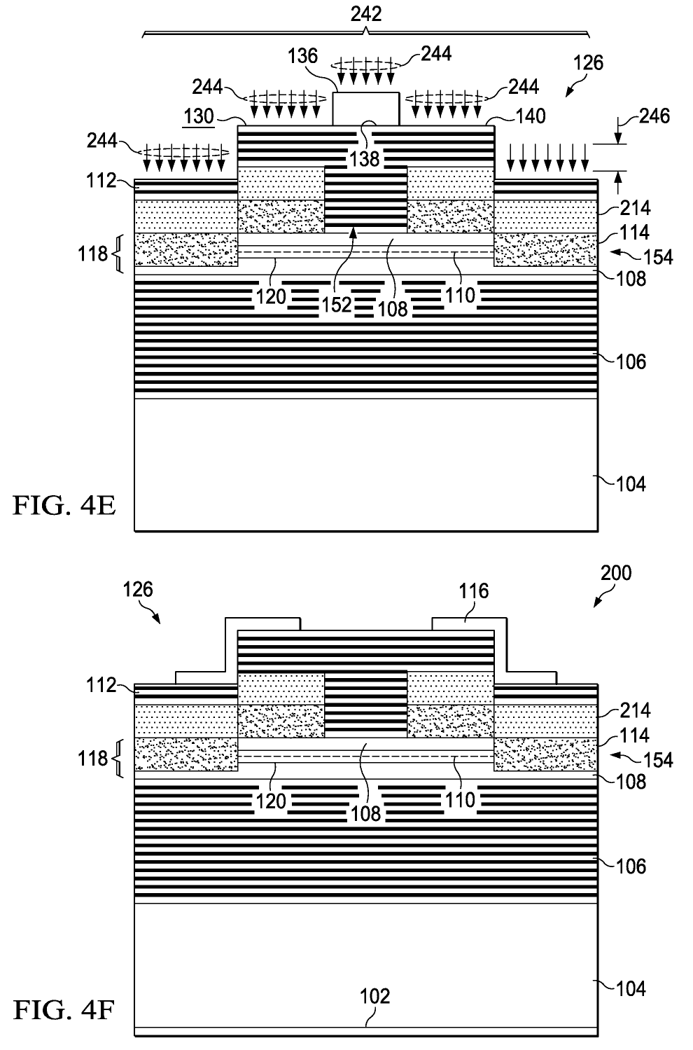

FIG. 3 is a diagram illustrating an embodiment of a VCSEL 200 constructed, at least in part, using a method or process generally depicted in FIGS. 4A-4F. Referring to FIG. 4A, the process begins with a wafer portion 126, which may be cut into an individual die used to form VCSEL 200. As shown in FIG. 4A, wafer portion 126 generally includes substrate 104, lower mirror stack 106, non-mirror layer 108 with a p-n junction 110, and top mirror stack 112. Referring to FIG. 4B, top mirror stack 112 is subjected to a photolithography or lift-off process to etch a desired pattern into top mirror stack 112 and form elevated structure 128.

After elevated structure 128 of FIG. 4B has been formed, implant resist 136 is placed on at least a portion of top surface 130 of elevated structure 128 as illustrated in FIG. 4C. Thereafter, as illustrated in FIG. 4D, wafer portion 126 is subjected to an ion implantation process 142. During ion implantation process 142, the ions are implanted into VCSEL 200 into top mirror stack 112 beneath exposed surface 140 and into a lower portion of top mirror stack 112 beneath neighboring mirror stack surface 132 using an implant energy (represented in FIG. 4D by a length 146 of arrows 144) to cause damage and/or otherwise render non-conductive a portion of VCSEL 200 at a predetermined depth and/or a desired location. Still referring to FIG. 4D, the implantation of ions into VCSEL 200 causes crystal damage that collectively produces gain guide implant 114.

Referring to FIG. 4E, wafer portion 126 is subjected to a supplemental ion implantation process 242. During supplemental ion implantation process 242, ions are implanted into top mirror stack 112 beneath exposed surface 140 and into a lower portion of top mirror stack 112 beneath neighboring mirror stack surface 132 using a lower implant energy relative to the implant energy used to form gain guide implant 114. The lower implant energy is represented in FIG. 4E by a length 246 of arrows 244 and causes damage and/or otherwise renders non-conductive a portion of VCSEL 200 at a predetermined depth and/or a desired location. Still referring to FIG. 4E, the implantation of ions into top mirror stack 112 causes crystal damage that collectively produces a gain guide implant 214.

As shown in FIG. 4E, gain guide implant 214 is immediately adjacent to, and disposed vertically above, gain guide implant 114. Forming gain guide implant 214 directly over gain guide implant 114 within VCSEL 200 ensures that no conducting gap exists between inner portion 148 and outer portion 150 of gain guide implant 114 where current could undesirably leak. In other words, gain guide implant 214 functions as a supplemental non-conducting layer in VCSEL 200 ensuring that current flows through conducting opening 152. In addition, if gain guide 114 was inadvertently formed too deep beneath exposed portion 140, gain guide implant 214 ensures that active region 120 beneath exposed portion 140 is still spanned.

After gain guide implant 114 and gain guide implant 214 have been formed by ion implantation process 142 of FIG. 4D and ion implantation process 242 of FIG. 4E, respectively, implant resist 136 is removed and top electrical contact 116 and lower electrical contact 102 are added to wafer portion 126 as shown in FIG. 4F, thereby producing VCSEL 200 as illustrated in FIG. 3.

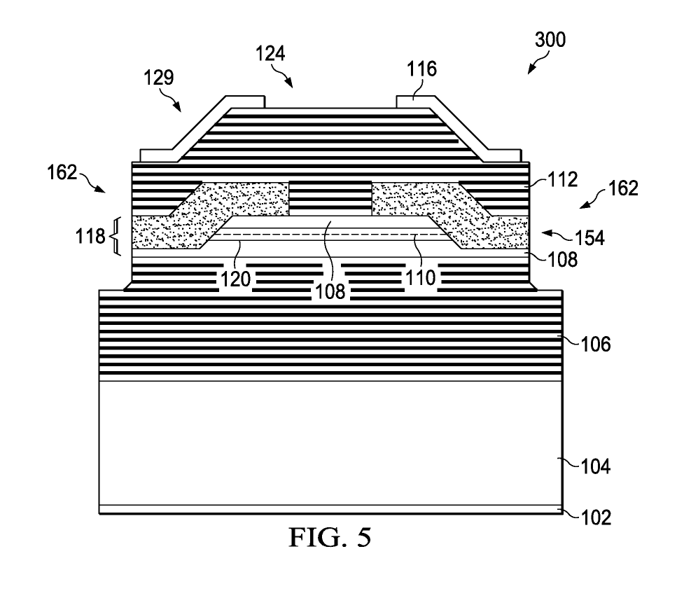

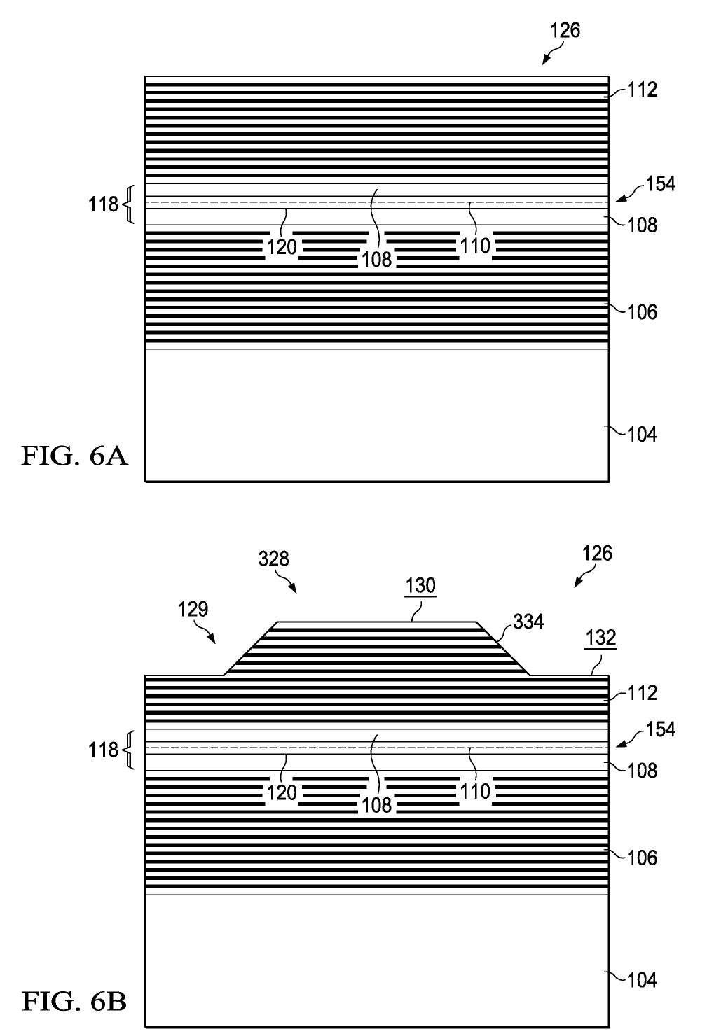

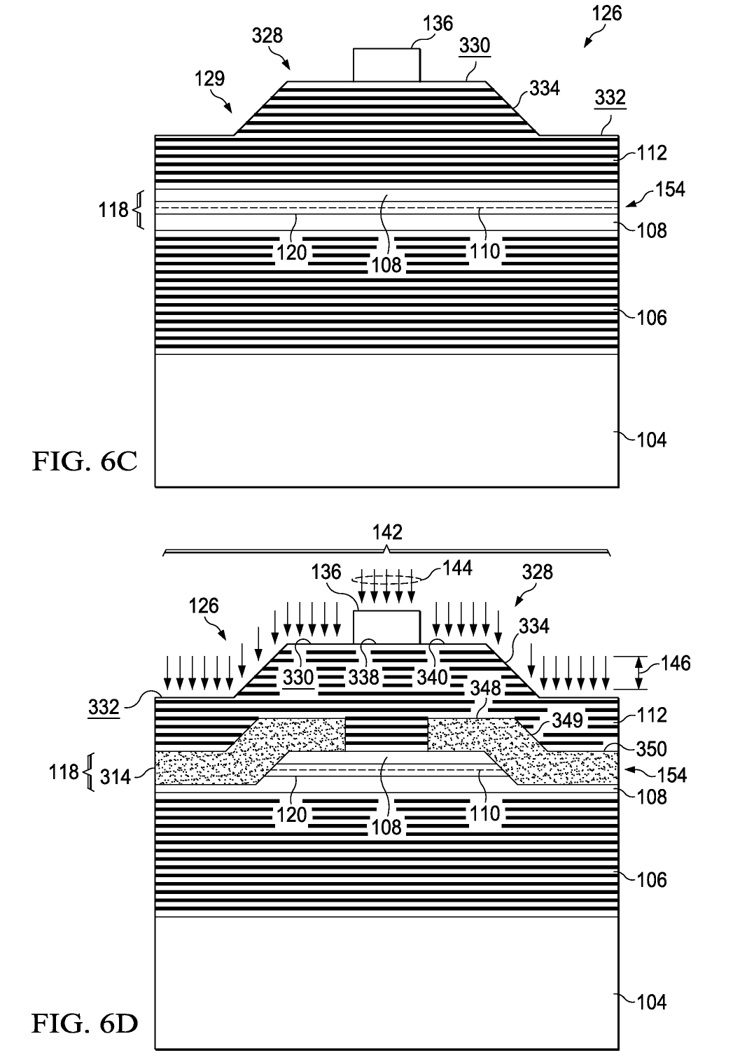

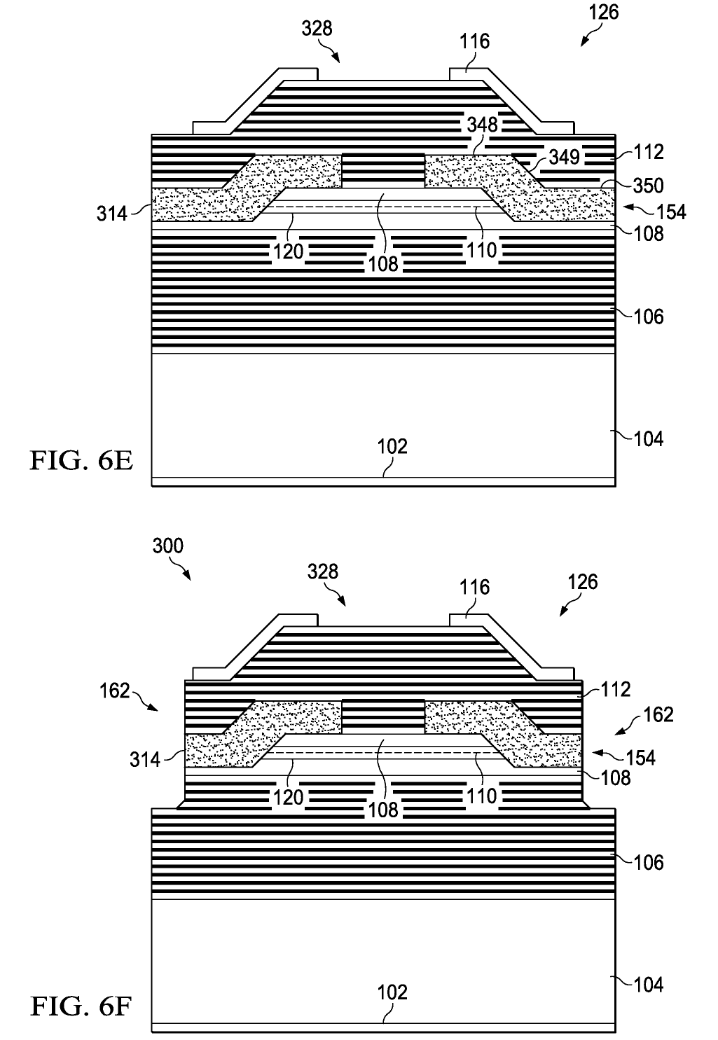

FIG. 5 is a diagram illustrating an embodiment of a VCSEL 300 constructed, at least in part, using a method or process generally depicted in FIGS. 6A-6F. Referring to FIG. 6A, the process begins with a wafer portion 126, which may be cut into an individual die used to form VCSEL 300. As shown in FIG. 6A, wafer portion 126 generally includes substrate 104, lower mirror stack 106, non-mirror layer 108 with a p-n junction 110, and top mirror stack 112. Referring to FIG. 6B, an elevated structure 328 is formed using, for example, photolithography or a lift-off process to produce a desired pattern in top mirror stack 112 by removing portions of top mirror stack in region 129. In the embodiment illustrated in FIG. 6B, side walls 334 of elevated structure 338 are tapered between a top surface 330 of elevated structure 328 and a neighboring mirror stack surface 332.

After elevated structure 328 of FIG. 6B has been formed, an implant resist 136 is placed on or above at least a portion of top surface 330 of elevated structure 328 as illustrated in FIG. 6C. Implant resist 136 generally divides top surface 330 into a covered portion 338 and an exposed portion 340. Thereafter, as illustrated in FIG. 6D, wafer portion 126 is subjected to ion implantation process 142. During ion implantation process 142, ions are implanted into VCSEL 300 beneath exposed surface 340, beneath an exposed portion of side wall 334, and into a lower portion of top mirror stack 112 beneath neighboring mirror stack surface 332 using an ion implant energy represented in FIG. 6D by a length 146 of arrows 144. Still referring to FIG. 6D, the implantation of ions into VCSEL 300 causes crystal damage and/or otherwise renders non-conductive a portion of VCSEL 300 that collectively produces a gain guide implant 314. As shown in FIG. 6D, gain guide implant 314 includes a tapered portion 349 extending between and coupling together an inner portion 348 gain guide implant 314 with an outer portion 350 gain guide implant 314. Either one or both of outer portion 350 and tapered portion 349 span across active region 120.

After gain guide implant 314 with tapered portion 349 has been formed by ion implantation process 142 of FIG. 6D, implant resist 136 is removed and top electrical contact 116 and lower electrical contact 102 are added to wafer portion 126 as shown in FIG. 6E. Thereafter, an isolation moat 162 is formed as shown in FIG. 6F. Isolation moat 162, which may be formed using a photolithography process or a lift-off process, generally progresses vertically along top mirror stack 112 and beyond active region 120 to form a boundary between VCSEL 300 and adjacent lasers in the wafer. Isolation moat 162 is generally transverse with p-n junction 110 and mirror layers of mirror stack 112. Isolation moat 162 enables individual testing of VCSEL 300 as shown in FIG. 5 prior to VCSEL 300 being separated from the wafer. In addition to being formed on VCSEL 300, it should be understood that isolation moat 162 may be formed on each of the other depicted lasers of the present disclosure (e.g., VCSEL 100, VCSEL 200, etc.) described and illustrated herein.

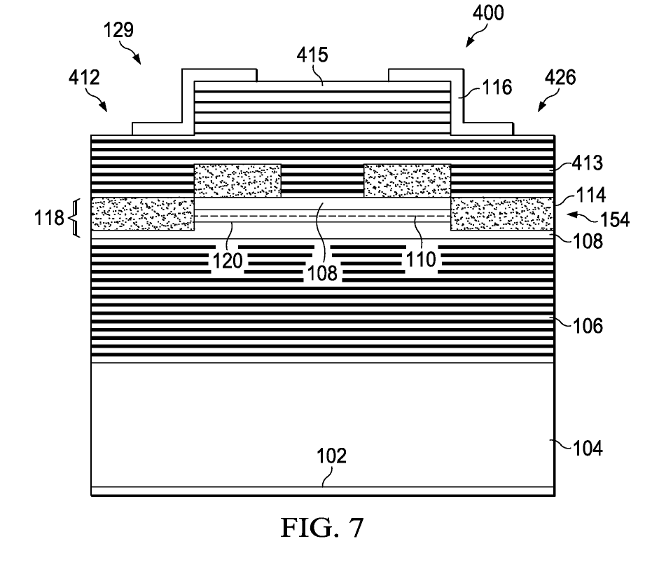

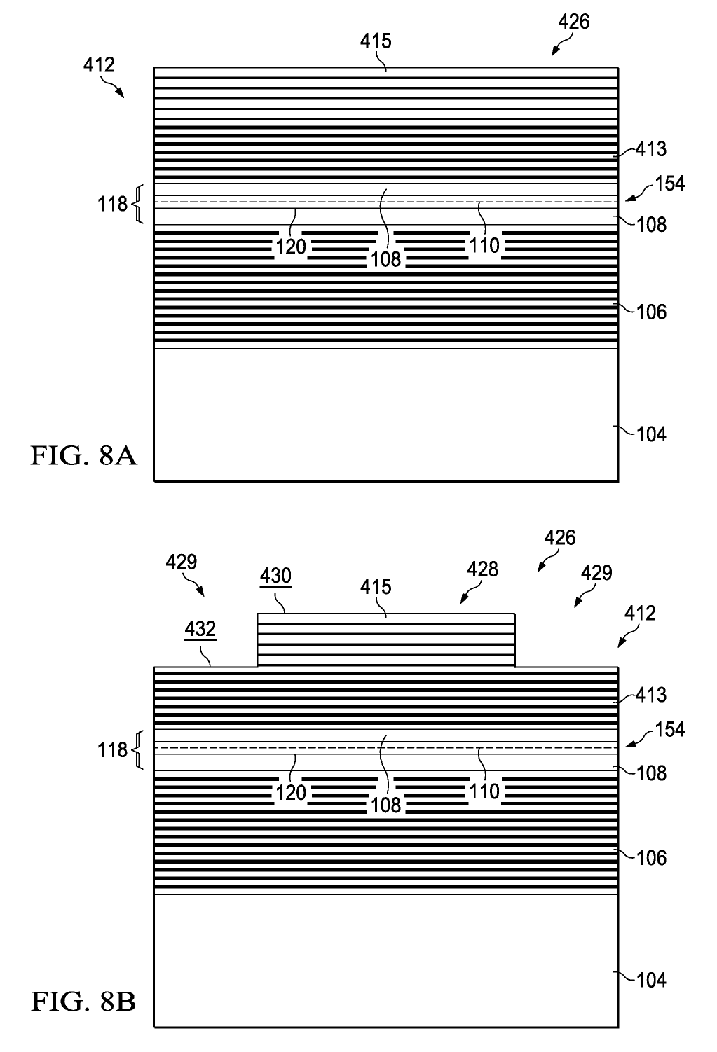

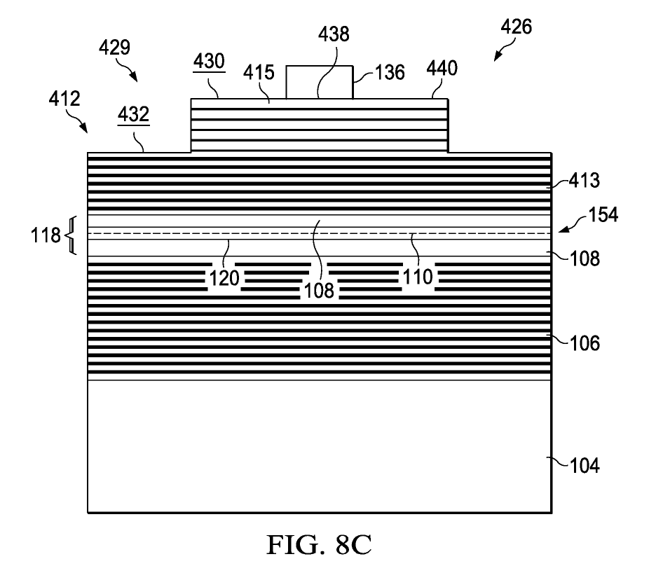

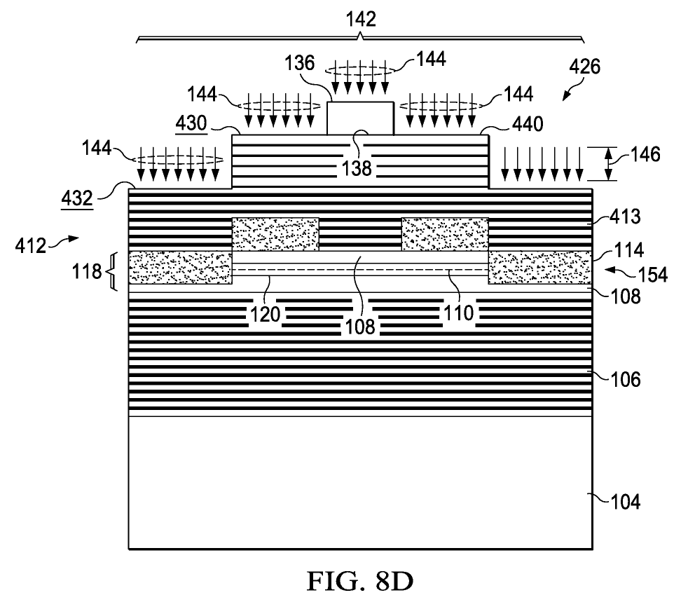

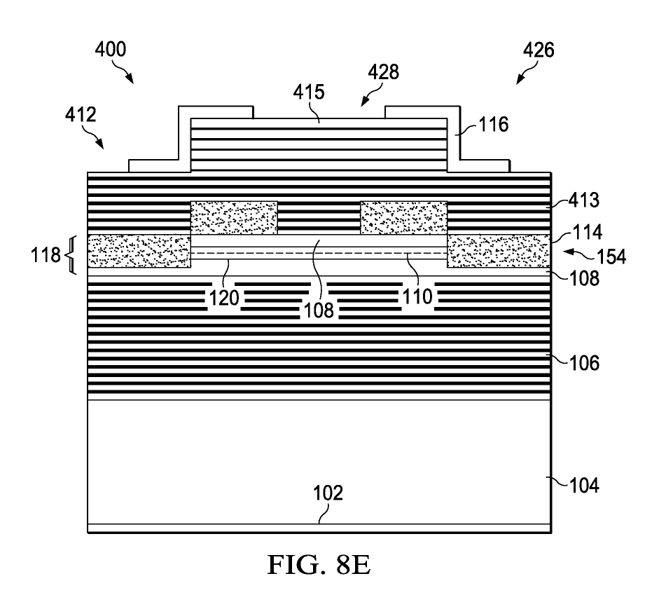

FIG. 7 is a diagram illustrating an embodiment of a VCSEL 400 constructed, at least in part, using a method or process generally depicted in FIGS. 8A-8E. Referring to FIG. 8A, the process begins with a wafer portion 426, which may be cut into an individual die used to form VCSEL 400. As shown in FIG. 8A, wafer portion 426 generally includes substrate 104, lower mirror stack 106, non-mirror layer 108 with a p-n junction 110, and a top mirror stack 412 formed from both semiconductor mirror layers 413 and either metal or optical dielectric mirror layers 415.

Referring to FIG. 8B, an elevated structure 428 of a desired pattern is formed by removing a portion of mirror layers 415 in region 429 using, for example, photolithography or a lift-off process. Elevated structure 428 in FIG. 8B may be formed from a metal such as gold. Elevated structure 428 may also be formed from an optical dielectric material such as (listed in approximate order of increasing refractive index) MgF₂, SiO₂, Al₂O₃, SiO, Si₃N₄, ZrO₂, HfO₂, TiO₂, and Si. Any appropriate pairs of these optical dielectric materials may be used as dielectric mirrors, with a greater or lesser index ratio. If either metal or dielectric material layers are sufficiently thick, elevated structure 428 may be made from fewer layers (e.g., made thinner) than other elevated structures (e.g., elevated structure 128 (FIGS. 2A-2E and 4A-4F), elevated structure 328 (FIGS. 6A-6F), etc.) and still result in appropriate location of gain guide implant 148.

After elevated structure 428 of FIG. 8B has been formed, an implant resist 136 is placed on or above at least a portion of a top surface 430 of elevated structure 428 as illustrated in FIG. 8C. Implant resist 136 generally divides top surface 430 into a covered portion 438 and an exposed portion 440. Thereafter, as illustrated in FIG. 8D, wafer portion 126 is subjected to an ion implantation process 142. During ion implantation process 142, ions are implanted into VCSEL 400 beneath exposed surface 440 and into semiconductor mirror layers 413 of top mirror stack 412 and beneath neighboring mirror stack surface 432 using an implant energy represented in FIG. 8D by a length 146 of arrows 144. Still referring to FIG. 8D, the implantation of ions into VCSEL 400 causes crystal damage and/or otherwise renders a portion of VCSEL 400 non-conductive and collectively produces gain guide implant 114. After gain guide implant 114 has been formed by ion implantation process 142 of FIG. 4D. Thereafter, implant resist 136 is removed and top electrical contact 116 and lower electrical contact 102 are added to wafer portion 126 as shown in FIG. 8E.

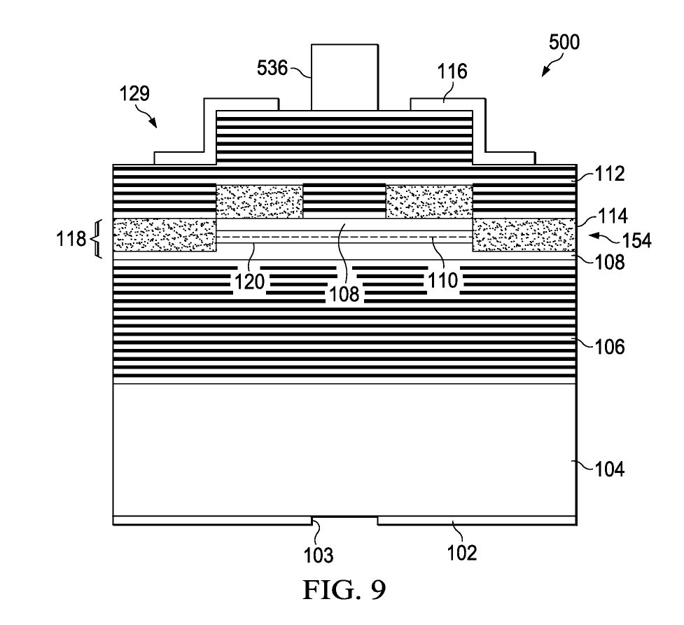

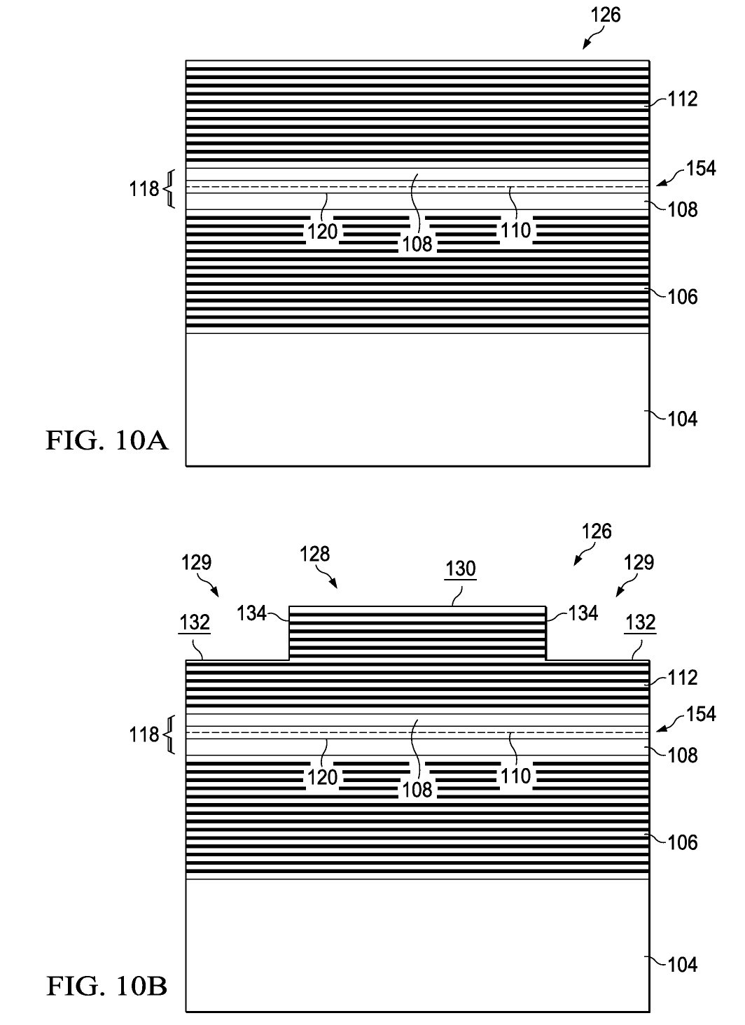

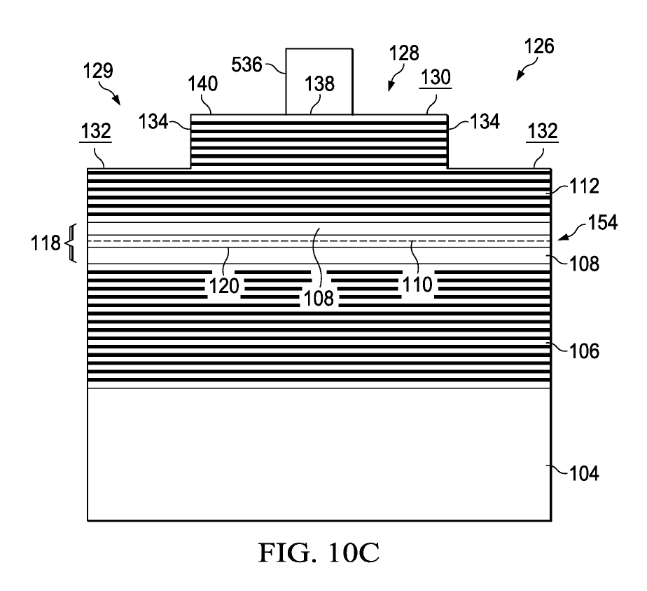

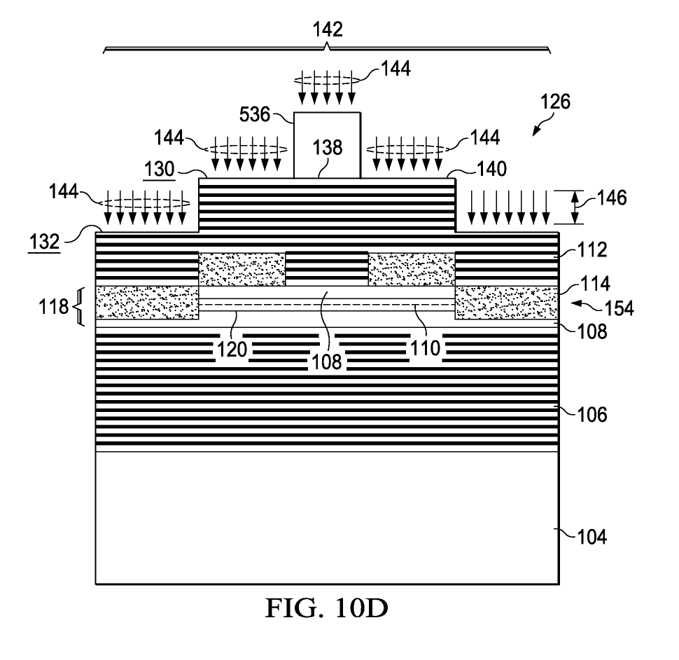

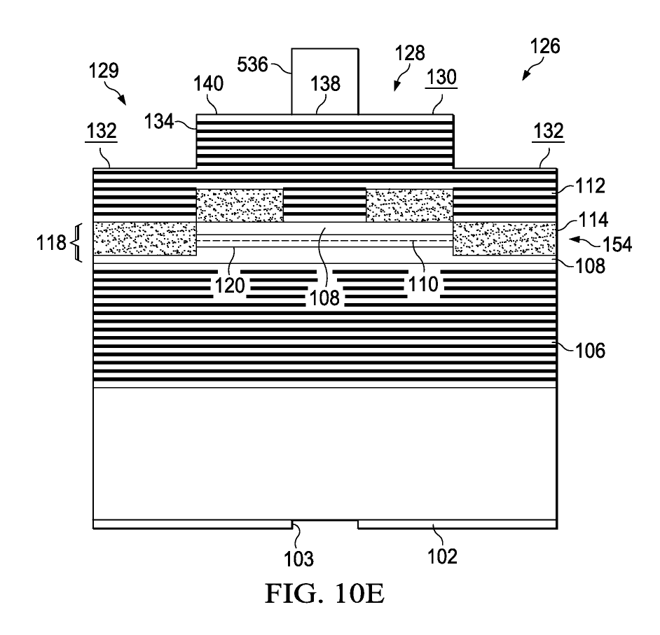

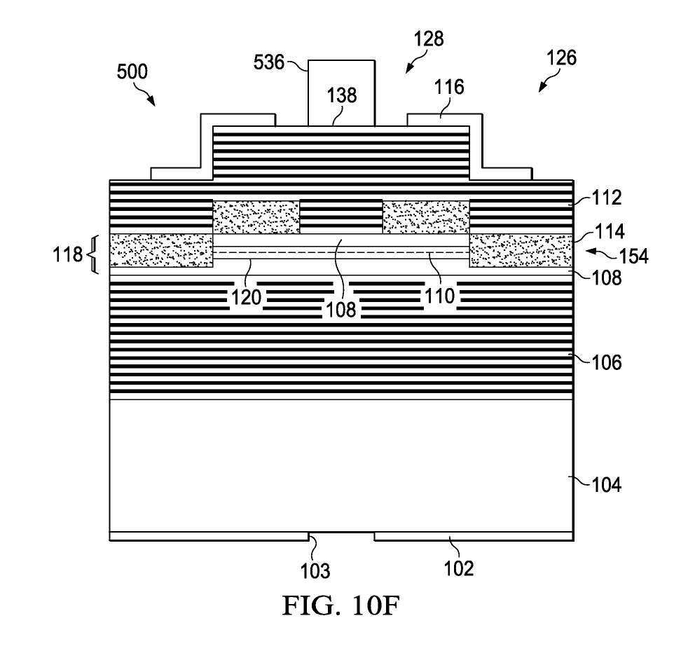

FIG. 9 is a diagram illustrating an embodiment of a VCSEL 500 constructed, at least in part, using the method or process generally depicted in FIGS. 10A-10F. As shown in FIG. 10A, the process begins with a wafer portion 126, which may be cut into an individual die used to form VCSEL 500. As shown in FIG. 10A, wafer portion 126 generally includes substrate 104, lower mirror stack 106, non-mirror layer 108 with a p-n junction 110, and top mirror stack 112. Referring to FIG. 10B, an elevated structure 128 having a desired pattern is formed using, for example, photolithography of a lift-off process by removing a portion of top mirror stack 112 in region 129.

After elevated structure 128 of FIG. 10B has been formed, an implant resist 536 made from a metal or a dielectric material is placed on at least a portion of top surface 130 of elevated structure 128 as illustrated in FIG. 10C. Implant resist 536 generally divides top surface 130 into covered portion 138 and an exposed portion 140. As shown, implant resist 536 may have a desired or predetermined vertical height or thickness (e.g., illustrated in FIGS. 10C-10F as having a greater thickness than implant resist 136 described and illustrated in FIGS. 3C and 3D, for example).

After implant resist 536 has been applied to top surface 130, wafer portion 126 is subjected to an ion implantation process 142 as illustrated in FIG. 10D. During ion implantation process 142, ions are implanted into VCSEL 500 beneath exposed surface 140 and into a lower portion of top mirror stack 112 beneath neighboring mirror stack surface 132 using an implant energy represented in FIG. 10D by a length 146 of arrows 144. Still referring to FIG. 10D, the implantation of ions into VCSEL 500 causes crystal damage and/or otherwise renders a portion of VCSEL 500 non-conductive that collectively produces gain guide implant 114.

After gain guide implant 114 has been formed by ion implantation process 142 of FIG. 10D, implant resist 536 is retained upon top surface 130 as shown in FIGS. 10E and 10F. If implant resist 536 is formed from a metal, only lower electrical contact 102 is added to wafer portion 126 and implant resist 536 is employed as the upper electrical contact (as shown in FIG. 10E). In this embodiment, an aperture 103 is patterned in lower electrical contact 102 to permit extraction of light from a lower side of the VCSEL 500. In addition, it is also possible with appropriate lithographic steps to put both electrical contacts on top mirror stack 112, in which case lower electrical contact 102 as shown in FIG. 10E may be omitted entirely. If implant resist 536 acts as the upper electrical contact, electrical contact 116 (e.g., shown in FIG. 9) may be omitted from VCSEL 500. If implant resist 536 is formed from a dielectric material, both top electrical contact 116 and lower electrical contact 102 are added to wafer portion 126 (as shown in FIG. 10F). In addition, implant resist 536 may impart certain properties to, or affect characteristics of, the light emitted from the laser.

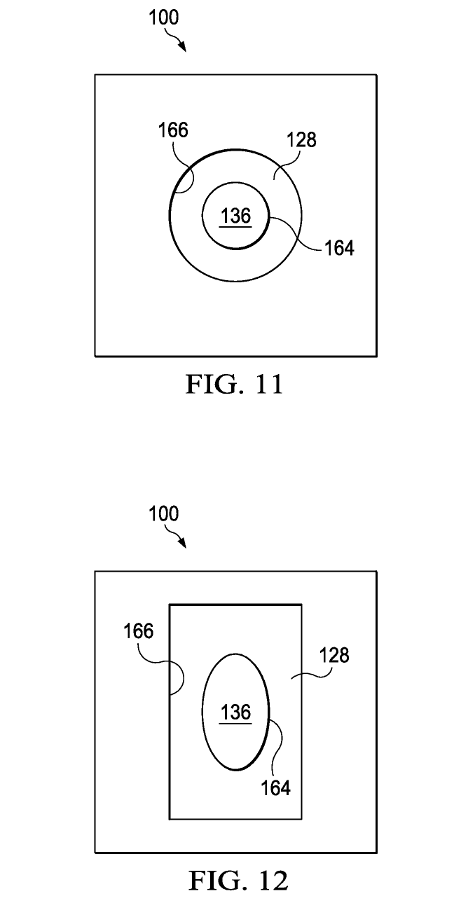

FIGS. 11 and 12 are diagrams illustrating different embodiments of forming elevated structure 128 and configuring implant resist 136 to produce a desired gain guide implant 114. Implant resist 136 and elevated structure 128 may be constructed to possess one of a variety of different shapes and/or patterns when viewed from above. For example, as shown in FIG. 11, a profile or periphery 164 of implant resist 136 and a profile or periphery 166 of elevated structure 128 may form concentric circles. In this embodiment, conducting opening 152 (FIG. 1) will be circular. In addition, the junction of inner portion 148 and outer portion 150 from gain guide implant 114 of FIG. 1 will overlap at a circular boundary.

In another example, as shown in FIG. 12, periphery 164 of implant resist 136 may be elliptical in shape while a periphery 166 of the elevated structure 128 may be rectangular. In this embodiment, conducting opening 152 (FIG. 1) will be elliptical. In addition, the junction of inner portion 148 and outer portion 150 of gain guide implant 114 will overlap at a rectangular boundary. In other embodiments, periphery 164 and periphery 166 may have other shapes such as, for example, a circle, an ellipse, a square, a truncated circle (i.e., which resembles a “D”), a regular polygon, and an irregular polygon. Thus, depending on the shape of periphery 164 selected for implant resist 136, VCSEL 100 or the other lasers described and illustrated herein (e.g., VCSEL 200, VCSEL 300, etc.) may be generated with conductive opening 152 that channels current in a particular manner to afford the laser with particular properties. Also, depending on the shape of periphery 166 selected for elevated structure 128, VCSEL 100 may be provided with stress and current injection asymmetries that permit polarization control.

Against the above backdrop, it should be understood that implant resist 136 (and in one embodiment implant resist 536) is responsible for the profile of conducting opening 152 passing through gain guide implant 114 (and in one embodiment either gain guide implant 214 or gain guide implant 314). In addition, it should be understood that elevated structure 128 (and in one embodiment either elevated structure 328 or elevated structure 428) is responsible for the profile or shape of the junction of inner portion 148 (i.e., the current constricting portion) and outer portion 150 (i.e. the isolating portion) of gain guide implant 114 and/or tapered portion 349 of gain guide implant 314. Thus, the shape of implant resist 136 may be defined to control the shape of conducting opening 152 in gain guide implant 114 while the shape of elevated structure 128 may be defined to control the shape of the isolation portion of gain guide implant 114.

In addition to the above, it should be noted that gain guide implant 114, gain guide implant 214, and guide implant 314 in FIGS. 1-10 may be produced in various types of lasers including, but not limited to, a mesa VCSEL, a vertical extended cavity surface emitting laser (VECSEL), a tunable VCSEL, a regrowth VCSEL, a VCSEL with intracavity contacts, and any other proton-implanted laser. Also, despite being shown and described as a top-emitting laser, VCSEL 100 may also be configured as a bottom-emitting laser with the appropriate design and by using a transparent substrate 104 and a patterned lower electrical contact 102.

Moreover, each of VCSEL 200, VCSEL 300, VCSEL 400, and VCSEL 500 may be constructed to function as a single mode, single emitter laser, a multi-mode, single-emitter laser, or a multi-emitter array of either type. In addition, each of these lasers may operate at various wavelengths including, for example, about eight hundred fifty nanometers (which includes wavelengths from 700 nm to 900 nm), about one thousand nanometers (which includes wavelengths from 950 to 1100 nm), about one thousand four hundred fifty nanometers (which includes wavelengths from 1350 to 1550 nm), and the like. It should also be understood that in the described methods, certain functions may be omitted, accomplished in a sequence different from that depicted in FIGS. 2A-2E, 4A-4F, 6A-6F, 8A-8E and 10A-10F, or simultaneously performed. Also, it should be understood that the methods depicted in FIGS. 2A-2E, 4A-4F, 6A-6F, 8A-8E and 10A-10F may be altered to encompass any of the other features or aspects as described elsewhere in the specification.

1. A method of forming a gain guide implant for a vertical cavity surface emitting laser (VCSEL), comprising:
implanting ions into a wafer to simultaneously form a first non-conducting portion of the gain guide implant spaced apart from an active region and a second non-conducting portion of the gain guide implant occupying the active region, the active region where electron-hole pairs recombine to emit photons, and wherein the first non-conducting portion is laterally offset relative to the second non-conducting portion.

2. The method of claim 1, further comprising forming an elevated structure on the wafer to form the first non-conducting portion vertically offset relative to the second non-conducting portion from the ion implantation.

3. The method of claim 2, further comprising placing an implant resist over a portion of the elevated structure to render a conducting opening in the first non-conducting portion.

4. The method of claim 1, further comprising forming an elevated structure in a top mirror stack of the wafer to form the first non-conducting portion vertically offset relative to the second non-conducting portion from the ion implantation.

5. The method of claim 1, further comprising forming an elevated structure on the wafer comprising either a dielectric material or a metal to form the first non-conducting portion vertically offset relative to the second non-conducting portion from the ion implantation.

6. The method of claim 1, further comprising forming an elevated structure having tapered side walls on the wafer to form the first non-conducting portion vertically offset relative to the second non-conducting portion from the ion implantation.

7. The method of claim 1, further comprising forming an isolation moat extending into a top mirror stack and the active region of the wafer to form a boundary relative to an adjacent laser.

8. A method of forming a vertical cavity surface emitting laser (VCSEL), comprising:
forming an elevated structure on a wafer;
applying an implant resist over at least a portion of the elevated structure; and
implanting ions through exposed portions of the wafer outside a periphery of the implant resist to form a gain guide implant having an inner portion offset from an active region and an outer portion extending into the active region, the active region where electron-hole pairs recombine to emit photons.

9. The method of claim 8, further comprising forming the elevated structure in a top mirror stack of the wafer.

10. The method of claim 8, further comprising forming the elevated structure from a dielectric material.

11. The method of claim 8, further comprising forming the elevated structure having a tapered side wall.

12. The method of claim 8, further comprising forming the elevated structure to produce the gain guide implant having a tapered portion connecting the inner portion with the outer portion.

13. The method of claim 8, further comprising forming an isolation moat extending into a top mirror stack and the active region of the wafer to form a boundary relative to an adjacent laser.

14. The method of claim 8, further comprising forming the elevated structure from a metal.

15. The method of claim 8, further comprising configuring the implant resist to produce a conducting opening in the inner portion of the gain guide implant.

16. A method of forming a vertical cavity surface emitting laser (VCSEL), comprising:
forming an elevated structure on a top surface of a wafer;
masking a portion of the elevated structure; and
implanting ions through unmasked portions of the top surface of the wafer to form a gain guide implant, the gain guide implant having a conducting opening in a top mirror stack of the wafer corresponding to a location of the masking, the gain guide implant extending at least partially into an active region of the wafer in a location laterally offset from the elevated structure, the active region where electron-hole pairs recombine to emit photons.

17. The method of claim 16, further comprising forming the elevated structure with a tapered side wall.

18. The method of claim 16, further comprising forming the elevated structure in the top mirror stack of the wafer.

19. The method of claim 16, further comprising forming an isolation moat extending into the top mirror stack and the active region of the wafer to form a boundary relative to an adjacent laser.

20. The method of claim 16, further comprising forming the gain guide implant having a tapered portion extending from the top mirror stack into the active region.

21. A method of forming a gain guide implant for a vertical cavity surface emitting laser (VCSEL), comprising:
implanting ions into a wafer to simultaneously form a first non-conducting portion of the gain guide implant spaced apart from an active region and a second non-conducting portion of the gain guide implant laterally offset relative to the first non-conducting portion, the second non-conducting portion laterally bordering a lateral boundary of the active region.
